(19) United States
(12) Patent Application Publication
(10) Pub. No.: US 2026/0180512 A1
(43) Pub. Date: Jun. 25, 2026

(54) DYNAMIC AMPLIFIER

(71) Applicant: REALTEK SEMICONDUCTOR CORPORATION, HSINCHU (TW)

(72) Inventor: SHIH-HSIUNG HUANG, HSINCHU (TW)

(21) Appl. No.: 19/422,031

(22) Filed: Dec. 16, 2025

(30) Foreign Application Priority Data
Dec. 23, 2024 (TW) 113150224

(51) Int. Cl. H03F 1/02; H03F 3/04

(52) U.S. Cl. CPC H03F 1/0211; H03F 3/04

(57) ABSTRACT

A dynamic amplifier includes a power supply circuit and first to fourth transistors. The power supply circuit is configured to provide power voltages. The first transistor is configured to be biased by a first auxiliary signal and to receive a first power voltage in the power voltages. The second transistor is configured to be biased by a second auxiliary signal and to receive the first power voltage. The third transistor is configured to receive the power voltages and generate a first output signal according to a first input signal. The fourth transistor is configured to receive the power voltages and generate a second output signal according to a second input signal, in which the third transistor is configured to receive the first power voltage via the first transistor, and the fourth transistor is configured to receive the first power voltage via the second transistor.

### BACKGROUND OF THE INVENTION

### 1. Field of the Invention

The present disclosure relates to a dynamic amplifier, and more particularly to a dynamic amplifier that improves power supply rejection ratio.

### 2. Description of Related Art

Power supply rejection ratio (PSRR) is a key indicator for evaluating the ability of an amplifier to maintain the stability of its output signal when a power voltage varies. A high PSRR amplifier may effectively suppress the influence of fluctuations in the power voltage on the output signal, thereby ensuring the accuracy and integrity of the signal. In the existing approaches, the power voltage is often subjected to noise or disturbances caused by various factors. Traditional dynamic amplifiers are unable to sufficiently resist these power supply interferences, resulting in the output signal being affected and thus reducing overall performance and reliability.

### SUMMARY OF THE INVENTION

In some aspects, an object of the present disclosure is, but not limited to, providing a dynamic amplifier that improves power supply rejection ratio, so as to make an improvement to the prior art.

In some aspects, a dynamic amplifier includes a power supply circuit, a first transistor, a second transistor, a third transistor, and a fourth transistor. The power supply circuit is configured to provide a plurality of power voltages. The first transistor is configured to be biased by a first auxiliary signal and to receive a first power voltage in the plurality of power voltages. The second transistor is configured to be biased by a second auxiliary signal and to receive the first power voltage. The third transistor is configured to receive the plurality of power voltages and configured to generate a first output signal according to a first input signal. The fourth transistor is configured to receive the plurality of power voltages and configured to generate a second output signal according to a second input signal, in which the third transistor is configured to receive the first power voltage via the first transistor, and the fourth transistor is configured to receive the first power voltage via the second transistor.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a schematic diagram of a dynamic amplifier according to some embodiments of the present disclosure.

FIG. 2 illustrates a schematic diagram of a dynamic amplifier according to some embodiments of the present disclosure.

FIG. 3 illustrates a schematic diagram of a dynamic amplifier according to some embodiments of the present disclosure.

FIG. 4 illustrates a schematic diagram of a dynamic amplifier according to some embodiments of the present disclosure.

FIG. 5 illustrates a schematic diagram of a dynamic amplifier according to some embodiments of the present disclosure.

FIG. 6 illustrates a schematic diagram of a dynamic amplifier according to some embodiments of the present disclosure.

FIG. 7 illustrates a schematic diagram of a dynamic amplifier according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuit” may indicate an object, which is formed with one or more transistors and/or one or more active/passive elements according to a specific arrangement, for processing signals.

As used herein, the term “and/or” includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, similar/identical elements in various figures are designated with the same reference number.

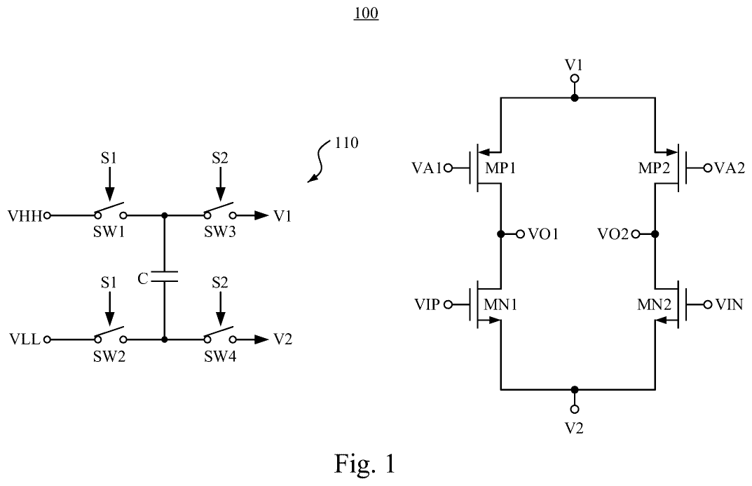

FIG. 1 illustrates a schematic diagram of a dynamic amplifier 100 according to some embodiments of the present disclosure. The dynamic amplifier 100 includes a power supply circuit 110, a transistor MP1, a transistor MP2, a transistor MN1, and a transistor MN2.

The power supply circuit 110 may be configured to provide a power voltage V1 and a power voltage V2. For example, the power supply circuit 110 may provide the power voltage V1 and the power voltage V2 according to a switching signal S1 and a switching signal S2. In some embodiments, the power supply circuit 110 may include a switch SW1, a switch SW2, a capacitor C, a switch SW3 and a switch SW4. A first terminal of the switch SW1 receives a supply voltage VHH, a second terminal of the switch SW1 is coupled to a first terminal of the capacitor C, and a control terminal of the switch SW1 receives the switching signal S1. A first terminal of the switch SW2 receives a supply voltage VLL, a second terminal of the switch SW2 is coupled to a second terminal of the capacitor C, and a control terminal of the switch SW2 receives the switching signal S1. A first terminal of the switch SW3 is coupled to the first terminal of the capacitor C, a second terminal of the switch SW3 outputs the power voltage V1, and a control terminal of the switch SW3 receives the switching signal S2. A first terminal of the switch SW4 is coupled to the second terminal of the capacitor C, a second terminal of the switch SW4 outputs the power voltage V2, and a control terminal of the switch SW4 receives the switching signal S2. With the above arrangement, the switch SW1 and the switch SW2 may be configured to be turned on according to the switching signal S1 to respectively provide the supply voltage VHH and the supply voltage VLL to the capacitor C, such that the capacitor C may be charged by the supply voltage VHH and the supply voltage VLL. The switch SW3 and the switch SW4 may be configured to be turned on according to the switching signal S2 to respectively output a voltage on the first terminal of the capacitor C as the power voltage V1, and to output a voltage on the second terminal of the capacitor C as the power voltage V2. In other words, when the switch SW1 and the switch SW2 are turned on, the switch SW3 and the switch SW4 are not turned on, and the capacitor C may be charged by the supply voltage VHH and the supply voltage VLL. Then, when the switch SW3 and the switch SW4 are turned on, the switch SW1 and the switch SW2 are not turned on, such that the switch SW3 and the switch SW4 may accordingly provide the power voltage V1 and the power voltage V2.

A first terminal (e.g., a source) of the transistor MP1 receives the power voltage V1, a second terminal (e.g., a drain) of the transistor MP1 is coupled to a first terminal (e.g., a drain) of the transistor MN1 and is configured to provide an output signal VO1, and a control terminal (e.g., a gate) of the transistor MP1 receives an auxiliary signal VA1. A first terminal of the transistor MP2 receives the power voltage V1, a second terminal of the transistor MP2 is coupled to a first terminal of the transistor MN2 and is configured to provide an output signal VO2, and a control terminal of the transistor MP2 receives an auxiliary signal VA2. A second terminal (e.g., a source) of the transistor MN1 receives the power voltage V2, and a control terminal (e.g., a gate) of the transistor MN1 receives an input signal VIP. A second terminal of the transistor MN2 receives the power voltage V2, and a control terminal of the transistor MN2 receives an input signal VIN.

In greater detail, one terminal of the transistor MN2 is coupled to the transistor MP2 to receive the power voltage V1 and generate the output signal VO2, another terminal of the transistor MN2 receives the power voltage V2, and a control terminal of the transistor MN2 receives the input signal VIN. One terminal of the transistor MP2 receives the power voltage V1, another terminal of the transistor MP2 is coupled to the transistor MN2, and a control terminal of the transistor MP2 receives the auxiliary signal VA2.

With the above arrangement, the transistor MP1 may be biased by the auxiliary signal VA1. The transistor MP2 may be biased according to the auxiliary signal VA2. The transistor MN1 may generate the output signal VO1 according to the input signal VIP and receive the power voltage V1 via the transistor MP1. The transistor MN2 may generate the output signal VO2 according to the input signal VIN and receive the power voltage V1 via the transistor MP2. In this example, the transistor MN1 may operate as a common-source amplifier and the transistor MP1 may operate as an active load of this amplifier. Similarly, the transistor MN2 may operate as another common-source amplifier and the transistor MP2 may operate as an active load of this amplifier.

In some embodiments, the supply voltage VHH and the supply voltage VLL may be provided from a low-dropout regulator and/or a switching power regulator, but the present disclosure is not limited thereto. If there is an unexpected voltage jitter on the supply voltage VHH, a corresponding voltage jitter may be formed on the power voltage V1. As the transistor MN1 receives the power voltage V1 via the transistor MP1, the voltage jitter on the power voltage V1 mainly affects the load impedance of the transistor MP1 and does not directly affect the transconductance of the transistor MN1. Similarly, as the transistor MN2 receives the power voltage V1 via the transistor MP2, the voltage jitter on the power voltage V1 mainly affects the load impedance of the transistor MP2 and does not directly affect the transconductance of the transistor MN2. As a result, the quality of the output signal VO1 and the output signal VO2 may be improved, thereby improving the power supply rejection ratio (PSRR) of the dynamic amplifier 100.

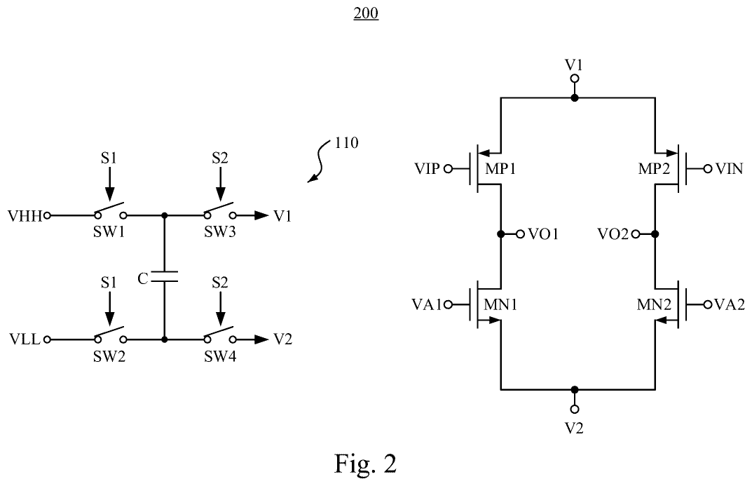

FIG. 2 illustrates a schematic diagram of a dynamic amplifier 200 according to some embodiments of the present disclosure. Different from FIG. 1, in this example, a control terminal of the transistor MP1 receives the input signal VIP and generates the output signal VO1 accordingly, and a control terminal of the transistor MN1 receives the auxiliary signal VA1 so as to be biased by the auxiliary signal VA1 to operate as an active load of the transistor MP1. Similarly, the transistor MP2 receives the input signal VIN and generates the output signal VO2 accordingly, and the transistor MN2 is biased by the auxiliary signal VA2 to operate as an active load of the transistor MP2.

In this example, one terminal of the transistor MP1 receives the power voltage V1, and another terminal of the transistor MP1 receives the power voltage V2 via the transistor MN1, and the transistor MP2 receives the power voltage V2 via the transistor MN2. One terminal of the transistor MN1 receives the power voltage V2, and another terminal of the transistor MN1 is coupled to the transistor MP1. If there is an unexpected voltage jitter on the supply voltage VLL, a corresponding voltage jitter may be formed on the power voltage V2. As the transistor MP1 receives the power voltage V2 via the transistor MN1, the voltage jitter on the power voltage V2 mainly affects the load impedance of the transistor MN1 and does not directly affect the transconductance of the transistor MP1. Similarly, as the transistor MP2 receives the power voltage V2 via the transistor MN2, the voltage jitter on the power voltage V2 mainly affects the load impedance of the transistor MN2 and does not directly affect the transconductance of the transistor MP2. As a result, the quality of the output signal VO1 and the output signal VO2 may be improved, thereby improving the PSRR of the dynamic amplifier 200.

In some embodiments, the auxiliary signal VA1 in FIG. 1 or FIG. 2 may be a direct-current (DC) voltage to bias the transistor MP1. Similarly, in some embodiments, the auxiliary signal VA2 in FIG. 1 or FIG. 2 may be a DC voltage to bias the transistor MP2. The above settings regarding the auxiliary signal VA1 and the auxiliary signal VA2 are given for illustrative purposes, and the present disclosure is not limited thereto.

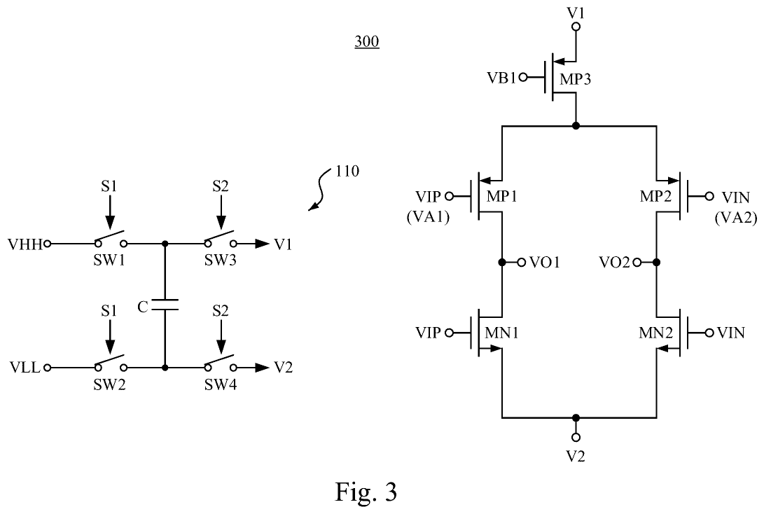

FIG. 3 illustrates a schematic diagram of a dynamic amplifier 300 according to some embodiments of the present disclosure. Different from FIG. 1, in this example, the auxiliary signal VA1 received by the transistor MP1 is the same as the input signal VIP, and the auxiliary signal VA2 received by the transistor MP2 is the same as the input signal VIN. As a result, the transistor MP1 and the transistor MN1 form an amplifier that amplifies the input signal VIP, and the transistor MP2 and the transistor MN2 form an amplifier that amplifies the input signal VIN.

In addition, compared with FIG. 1, in this example, the dynamic amplifier 300 further includes a transistor MP3. A first terminal of the transistor MP3 is coupled to the power supply circuit 110 to receive the power voltage V1, a second terminal of the transistor MP3 is coupled to first terminals of the transistor MP1 and the transistor MP2, and a control terminal of the transistor MP3 receives a bias voltage VB1. With the above arrangement, the transistor MP3 may be biased by the bias voltage VB1 and may receive the power voltage V1. The transistor MP1 and the transistor MP2 may be coupled to the transistor MP3 to receive the power voltage V1 via the transistor MP3. As a result, the transistor MP3 may provide further buffering protection to reduce the influence of voltage jitter on the power voltage V1, which is applied to the transistor MP1, the transistor MP2, the transistor MN1 and the transistor MN2.

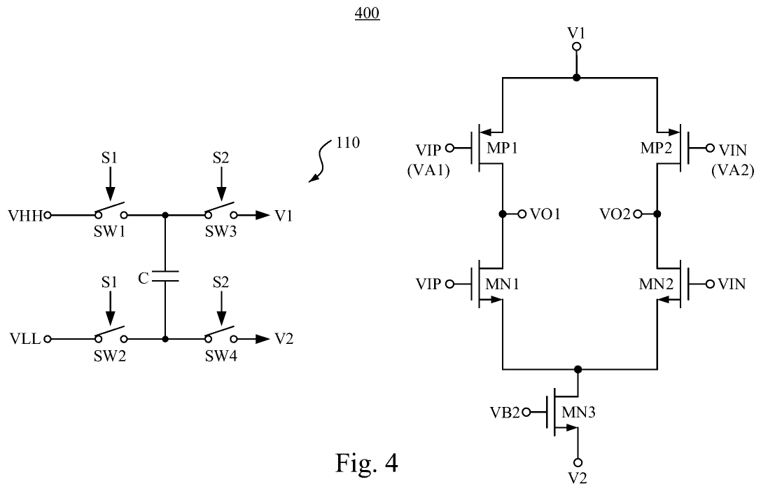

FIG. 4 illustrates a schematic diagram of a dynamic amplifier 400 according to some embodiments of the present disclosure. Different from FIG. 2, in this example, the auxiliary signal VA1 received by the transistor MP1 is the same as the input signal VIP, and the auxiliary signal VA2 received by the transistor MP2 is the same as the input signal VIN. As a result, the transistor MP1 and the transistor MN1 form an amplifier that amplifies the input signal VIP, and the transistor MP2 and the transistor MN2 form an amplifier that amplifies the input signal VIN.

Compared with FIG. 1, in this example, the dynamic amplifier 400 further includes a transistor MN3. A first terminal of the transistor MN3 is coupled to second terminals of the transistor MN1 and the transistor MN2, a second terminal of the transistor MN3 is coupled to the power supply circuit 110 to receive the power voltage V2, and a control terminal of the transistor MN3 receives a bias voltage VB2. With the above arrangement, the transistor MN3 may be biased by the bias voltage VB2 and may receive the power voltage V2. The transistor MN1 and the transistor MN2 may be coupled to the transistor MN3 to receive the power voltage V2 via the transistor MN3. As a result, the transistor MN3 may provide further buffering protection to reduce the influence of voltage jitter on the power voltage V2, which is applied to the transistor MP1, the transistor MP2, the transistor MN1 and the transistor MN2.

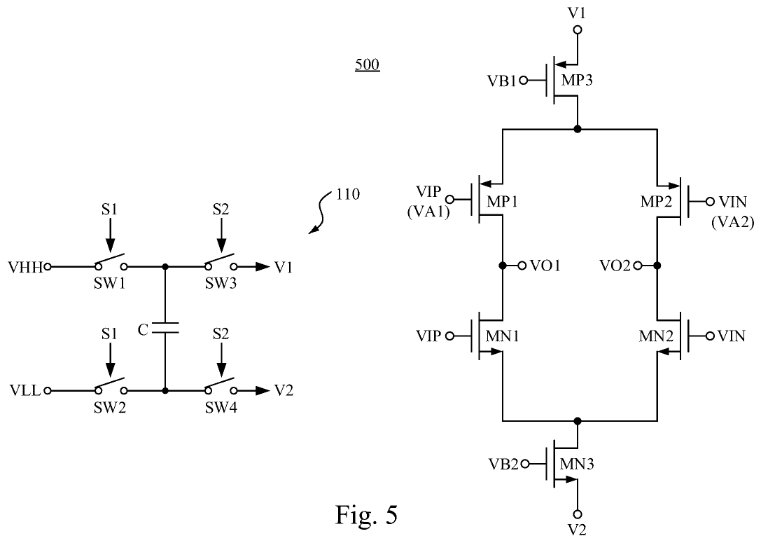

FIG. 5 illustrates a schematic diagram of a dynamic amplifier 500 according to some embodiments of the present disclosure. Compared with FIG. 3 and FIG. 4, the dynamic amplifier 500 includes the transistor MP3 and the transistor MN3 to implement more complete buffering protection. The related arrangement of the transistor MP3 and the transistor MN3 in FIG. 5 is the same as the arrangement in FIG. 3 and FIG. 4 and therefore will not be repeated here.

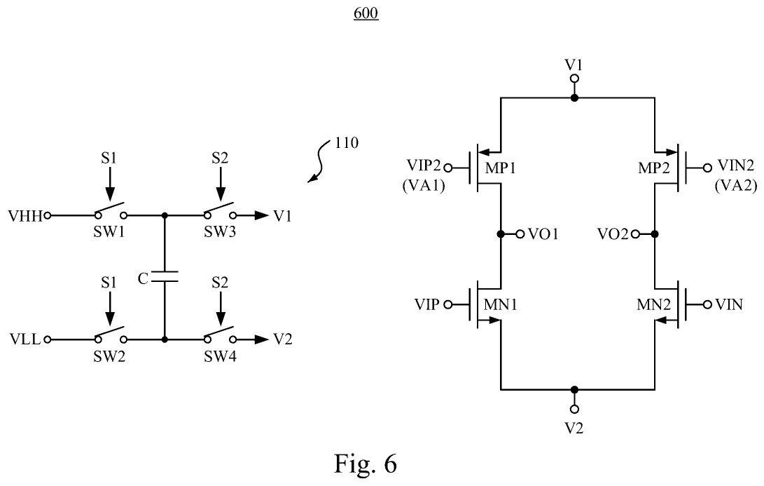

FIG. 6 illustrates a schematic diagram of a dynamic amplifier 600 according to some embodiments of the present disclosure. Compared with FIG. 1, in this example, the auxiliary signal VA1 and the auxiliary signal VA2 may be a pair of differential signals. For example, in this example, the transistor MP1 may receive an input signal VIP2 (which corresponds to the auxiliary signal VA1 of FIG. 1), the transistor MP2 may receive an input signal VIN2 (which corresponds to the auxiliary signal VA2 of FIG. 1), and the input signal VIP2 and the input signal VIN2 may be a pair of differential signals. With the above arrangement, the transistor MP1 and the transistor MN1 can, according to the input signal VIP2 and the input signal VIP, generate the output signal VO1 and provide corresponding buffering protection for each other. Similarly, the transistor MP2 and the transistor MN2 can, according to the input signal VIN2 and the input signal VIN, generate the output signal VO2 and provide corresponding buffering protection for each other.

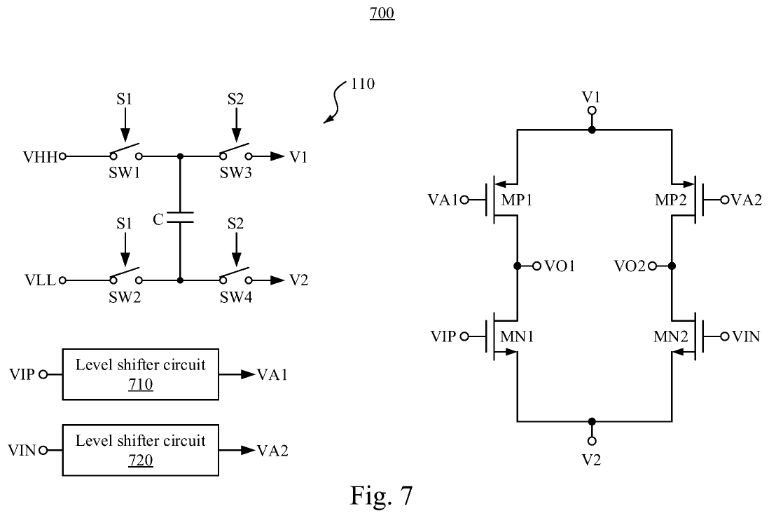

FIG. 7 illustrates a schematic diagram of a dynamic amplifier 700 according to some embodiments of the present disclosure. Compared with FIG. 1, in this example, the auxiliary signal VA1 may be a signal generated based on the input signal VIP, and the auxiliary signal VA2 may be a signal generated based on the input signal VIN. For example, the dynamic amplifier 700 may further include a level shifter circuit 710 and a level shifter circuit 720. The level shifter circuit 710 may generate the auxiliary signal VA1 according to the input signal VIP, such that the auxiliary signal VA1 and the input signal VIP have the same alternating-current (AC) signal component and have different DC levels. Similarly, the level shifter circuit 720 may generate the auxiliary signal VA2 according to the input signal VIN, such that the auxiliary signal VA2 and the input signal VIN have the same AC signal component and have different DC levels. In some embodiments, each of the level shifter circuit 710 and the level shifter circuit 720 may be implemented with a resistor and a capacitor. In some embodiments, each of the level shifter circuit 710 and the level shifter circuit 720 may be implemented with a transistor. The above implementations of the level shifter circuit 710 and the level shifter circuit 720 are given for illustrative purposes, and the present disclosure is not limited thereto.

It is understood that, in the above embodiments, transistors may be directly coupled, or may be coupled via other circuit components (for example, but not limited to, a resistor, a capacitor, a diode or another transistor). Therefore, the contemplated scope of the present disclosure is not limited to the arrangement shown in FIG. 1 to FIG. 7.

As described above, the dynamic amplifier provided in some embodiments of the present disclosure may utilize transistors to reduce interference of voltage jitter on power voltage, thereby increasing the overall power supply rejection ratio.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically include transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely some embodiments of the present disclosure, without any intention to limit the scope of the present disclosure thereto. Various equivalent changes, alterations, or modifications according to the claims of present disclosure are all consequently viewed as being embraced by the scope of the present disclosure.

What is claimed is:

1. A dynamic amplifier, comprising:
a power supply circuit configured to provide a plurality of power voltages;
a first transistor configured to be biased by a first auxiliary signal and to receive a first power voltage in the plurality of power voltages;
a second transistor configured to be biased by a second auxiliary signal and to receive the first power voltage;
a third transistor configured to receive the plurality of power voltages and to generate a first output signal according to a first input signal; and
a fourth transistor configured to receive the plurality of power voltages and to generate a second output signal according to a second input signal,
wherein the third transistor is configured to receive the first power voltage via the first transistor, and the fourth transistor is configured to receive the first power voltage via the second transistor.

2. The dynamic amplifier of claim 1, wherein a first terminal of the third transistor is coupled to the first transistor to receive the first power voltage and generate the first output signal, a second terminal of the third transistor receives a second power voltage of the power voltages, and a control terminal of the third transistor receives the first input signal.

3. The dynamic amplifier of claim 1, wherein a first terminal of the first transistor receives the first power voltage, a second terminal of the first transistor is coupled to the third transistor, and a control terminal of the first transistor receives the first auxiliary signal.

4. The dynamic amplifier of claim 1, wherein the first auxiliary signal and the second auxiliary signal are direct-current (DC) voltages, or are a pair of differential signals.

5. The dynamic amplifier of claim 1, wherein the first auxiliary signal is a signal generated based on the first input signal, and the second auxiliary signal is a signal generated based on the second input signal.

6. The dynamic amplifier of claim 1, wherein the first auxiliary signal and the first input signal are the same signal, and the second auxiliary signal and the second input signal are the same signal.

7. The dynamic amplifier of claim 1, further comprising:
a fifth transistor configured to be biased by a first bias voltage and to receive the first power voltage,
wherein the first transistor and the second transistor are coupled to the fifth transistor to receive the first power voltage via the fifth transistor.

8. The dynamic amplifier of claim 1, further comprising:
a fifth transistor configured to be biased by a second bias voltage and to receive a second power voltage in the plurality of power voltages,
wherein the third transistor and the fourth transistor are coupled to the fifth transistor to receive the second power voltage via the fifth transistor.

9. The dynamic amplifier of claim 1, further comprising:
a fifth transistor configured to be biased by a first bias voltage and to receive the first power voltage; and
a sixth transistor configured to be biased by a second bias voltage and to receive a second power voltage in the plurality of power voltages,
wherein the first transistor and the second transistor are coupled to the fifth transistor to receive the first power voltage via the fifth transistor, and the third transistor and the fourth transistor are coupled to the sixth transistor to receive the second power voltage via the sixth transistor.

10. The dynamic amplifier of claim 1, wherein the power supply circuit comprises:
a first switch configured to be turned on according to a first switching signal to provide a first supply voltage;
a second switch configured to be turned on according to the first switching signal to provide a second supply voltage;
a capacitor configured to be charged by the first supply voltage and the second supply voltage;
a third switch coupled to a first terminal of the capacitor and configured to be turned on according to a second switching signal to provide the first power voltage; and
a fourth switch coupled to a second terminal of the capacitor and configured to be turned on according to the second switching signal to provide a second power voltage in the plurality of power voltages.

11. The dynamic amplifier of claim 1, wherein a first terminal of the fourth transistor is coupled to the second transistor to receive the first power voltage and generate the second output signal, a second terminal of the fourth transistor receives a second power voltage of the power voltages, and a control terminal of the fourth transistor receives the second input signal.

12. The dynamic amplifier of claim 1, wherein a first terminal of the second transistor receives the first power voltage, a second terminal of the second transistor is coupled to the fourth transistor, and a control terminal of the second transistor receives the second auxiliary signal.

13. The dynamic amplifier of claim 1, wherein the first auxiliary signal and the first input signal have the same alternating-current (AC) signal component and have different direct-current levels.

14. The dynamic amplifier of claim 1, wherein the second auxiliary signal and the second input signal have the same AC signal component and have different DC levels.

15. The dynamic amplifier of claim 1, wherein the first auxiliary signal and the second auxiliary signal are a pair of differential input signals.
